(19) United States
(12) Patent Application Publication
(10) Pub. No.: US 2026/0075851 A1
(43) Pub. Date: Mar. 12, 2026

(54) SEMICONDUCTOR STRUCTURE INCLUDING 3D CAPACITOR AND METHOD FOR FORMING THE SAME

(71) Applicant: TAIWAN SEMICONDUCTOR MANUFACTURING COMPANY LTD., HSINCHU (TW)

(72) Inventors: SHIH-EN LAI, TAICHUNG CITY (TW); CHAN-YU HUNG, TAINAN CITY (TW); FEI-YUN CHEN, HSINCHU (TW)

(21) Appl. No.: 18/827,901

(22) Filed: Sep. 9, 2024

(51) Int. Cl. H01L 27/06; H01L 29/423; H01L 29/66

(52) U.S. Cl. CPC H10D 1/716; H10D 64/017; H10D 64/513; H10D 88/00

(57) ABSTRACT

A semiconductor 3D capacitor includes a semiconductor electrode disposed in a semiconductor substrate, a metal electrode over the semiconductor electrode, and an isolation structure between the semiconductor electrode and the metal electrode. The isolation structure includes a dielectric feature between the semiconductor electrode and the metal electrode, and a dielectric layer between the dielectric feature and the metal electrode. A bottom surface of the metal electrode is between a topmost surface of the dielectric feature and a bottom surface of the dielectric feature in a direction perpendicular to a surface of the semiconductor substrate.

### BACKGROUND

The semiconductor integrated circuit (IC) industry has experienced rapid growth. In the course of IC evolution, functional density (i.e., the number of interconnected devices per chip area) has generally increased while geometry size (i.e., the size of the smallest component (or line) that can be created using a fabrication process) has decreased. This scaling down process generally provides benefits by increasing production efficiency and lowering associated costs. Such scaling down has also increased the complexity of processing and manufacturing ICs, and for these advances to be realized, similar developments in IC manufacturing are needed.

For example, as the semiconductor industry has progressed into nanometer-scale process nodes in pursuit of greater device density, higher performance, and lower costs, challenges fin both fabrication and design have resulted in the development of three-dimensional (3D) devices. To facilitate the development of 3D devices, there is a need for capacitors for the 3D devices. Accordingly, although existing capacitors and methods of fabricating capacitors have been generally adequate for their intended purposes, they have not been entirely satisfactory in all respects. Therefore, further development in 3D capacitors is needed.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 is a flowchart representing a method for forming a semiconductor 3D capacitor according to aspects of the present disclosure.

FIG. 2 is a flowchart representing a method for forming a semiconductor structure including a 3D capacitor according to aspects of the present disclosure.

FIGS. 3A, 3B and 3C are cross-sectional views of different regions of a semiconductor structure including a 3D capacitor at a fabrication stage according to aspects of the present disclosure in one or more embodiments.

FIGS. 4A, 4B and 4C are cross-sectional views of the different regions of the semiconductor structure including the 3D capacitor at a fabrication stage subsequent to that of FIGS. 3A, 3B and 3C according to aspects of the present disclosure in one or more embodiments.

FIGS. 5A, 5B and 5C are cross-sectional views of the different regions of the semiconductor structure including the 3D capacitor at a fabrication stage subsequent to that of FIGS. 4A, 4B and 4C according to aspects of the present disclosure in one or more embodiments.

FIGS. 6A, 6B and 6C are cross-sectional views of the different regions of the semiconductor structure including the 3D capacitor at a fabrication stage subsequent to that of FIGS. 5A, 5B and 5C according to aspects of the present disclosure in one or more embodiments.

FIGS. 7A, 7B and 7C are cross-sectional views of the different regions of the semiconductor structure including the 3D capacitor at a fabrication stage subsequent to that of FIGS. 6A, 6B and 6C according to aspects of the present disclosure in one or more embodiments.

FIGS. 8A, 8B and 8C are cross-sectional views of the different regions of the semiconductor structure including the 3D capacitor at a fabrication stage subsequent to that of FIGS. 7A, 7B and 7C according to aspects of the present disclosure in one or more embodiments.

FIGS. 9A, 9B and 9C are cross-sectional views of the different regions of the semiconductor structure including the 3D capacitor at a fabrication stage subsequent to that of FIGS. 8A, 8B and 8C according to aspects of the present disclosure in one or more embodiments.

FIGS. 10A, 10B and 10C are cross-sectional views of different regions of a semiconductor structure including a 3D capacitor at a fabrication stage according to aspects of the present disclosure in one or more embodiments.

FIGS. 11A, 11B and 11C are cross-sectional views of the different regions of the semiconductor structure including the 3D capacitor at a fabrication stage subsequent to that of FIGS. 10A, 10B and 10C according to aspects of the present disclosure in one or more embodiments.

FIGS. 12A, 12B and 12C are cross-sectional views of the different regions of the semiconductor structure including the 3D capacitor at a fabrication stage subsequent to that of FIGS. 11A, 11B and 11C according to aspects of the present disclosure in one or more embodiments.

FIGS. 13A, 13B and 13C are cross-sectional views of the different regions of the semiconductor structure including the 3D capacitor at a fabrication stage subsequent to that of FIGS. 12A, 12B and 12C according to aspects of the present disclosure in one or more embodiments.

FIGS. 14A, 14B and 14C are cross-sectional views of the different regions of the semiconductor structure including the 3D capacitor at a fabrication stage subsequent to that of FIGS. 13A, 13B and 13C according to aspects of the present disclosure in one or more embodiments.

FIGS. 15A, 15B and 15C are cross-sectional views of the different regions of the semiconductor structure including the 3D capacitor at a fabrication stage subsequent to that of FIGS. 14A, 14B and 14C according to aspects of the present disclosure in one or more embodiments.

FIGS. 16 to 20 are cross-sectional views of a 3D capacitor at various fabrication stages according to aspects of the present disclosure in one or more embodiments.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about. ” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Aspects of the present invention provides a design for a 3D capacitor. The 3D capacitor may be a metal-insulator-metal (MIM) 3D capacitor or a metal-insulator-semiconductor (MIS) 3D capacitor. The 3D capacitor, for example, may be used in conjunction with a 3D device such as a FinFET device. The FinFET device may be, for example, a P-type metal-oxide-semiconductor (PMOS) FinFET device or an N-type metal-oxide-semiconductor (NMOS) FinFET device. The present disclosure depicts an MIS capacitor as an example of a FinFET device to illustrate various embodiments of the present disclosure. It should be understood, however, that the disclosure is not intended to be limited to a particular type of device, except as specifically claimed.

Further, the present disclosure provides a semiconductor structure including a 3D capacitor, a FinFET device, and a high voltage (HV) transistor device. In some embodiments, the present disclosure provides a method for integrating and forming a 3D capacitor, a FinFET device and an HV device. In such embodiments, a capacitance of the 3D capacitor is increased from a sidewall area. Further, the 3D device can be integrated in the FinFET approach and the HV device approach to the front-end-of-line (FEOL) manufacturing operations without adding extra photolithography.

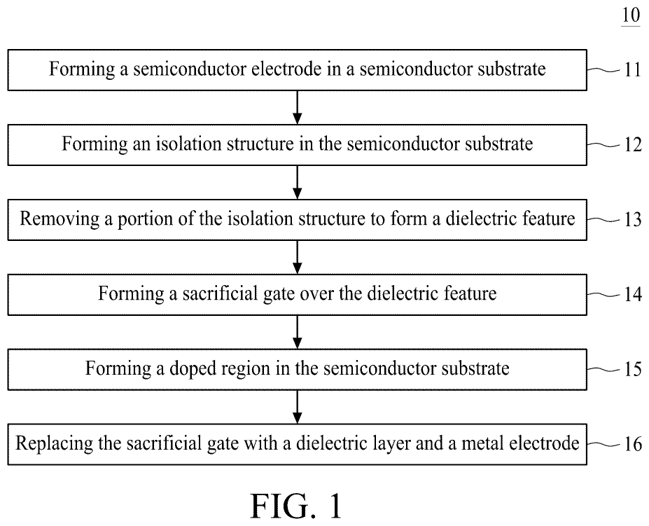

FIG. 1 is a flowchart representing a method for forming a 3D capacitor 10 according to aspects of the present disclosure. The method 10 includes a number of operations (11, 12, 13, 14, 15 and 16). The method 10 will be further described according to one or more embodiments. It should be noted that the operations of the method 10 may be rearranged or otherwise modified within the scope of the various aspects. It should be further noted that additional processes may be provided before, during, and after the method 10, and that some other processes may be only briefly described herein. Thus, other implementations are possible within the scope of the various aspects described herein.

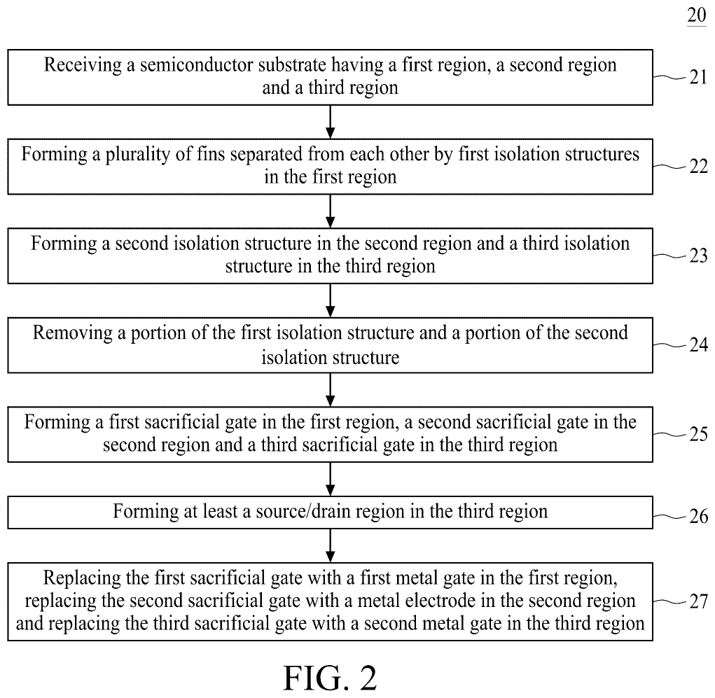

FIG. 2 is a flowchart representing a method for forming a semiconductor structure including a 3D capacitor 20 according to aspects of the present disclosure. The method 20 includes a number of operations (21, 22, 23, 24, 25, 26 and 27). The method 20 will be further described according to one or more embodiments. It should be noted that the operations of the method 20 may be rearranged or otherwise modified within the scope of the various aspects. It should be further noted that additional processes may be provided before, during, and after the method 20, and that some other processes may be only briefly described herein. Thus, other implementations are possible within the scope of the various aspects described herein. In some embodiments, the method 20 can be integrated into the method 10, but the disclosure is not limited thereto.

In some embodiments, the method 10 and the method 20 can be integrated.

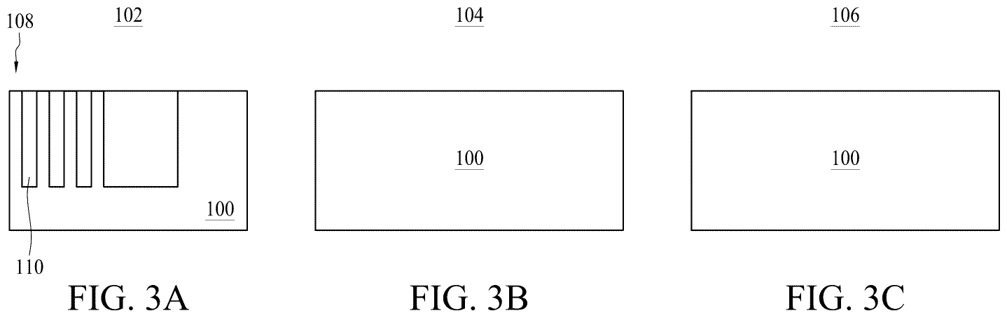

Referring to FIGS. 3A to 3C, in some embodiments, in operation 21, a semiconductor substrate 100 is received. In some embodiments, the semiconductor substrate 100 is a bulk silicon substrate. In other embodiments, the semiconductor substrate 100 includes an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or a combination thereof. In still other embodiments, the semiconductor substrate 100 includes a silicon-on-insulator (SOI) substrate. The SOI substrate can be fabricated using separation by ion implantation of oxygen (SIMOX), wafer bonding, and/or other suitable methods.

The semiconductor substrate 100 may have a first region 102, a second region 104 and a third region 106 defined thereon. In some embodiments, the first region 102 is used to accommodate a logic device, the second region 104 is used to accommodate a 3D capacitor, and the third region 106 is used to accommodate a high voltage (HV) device. In some embodiments, the logic device may be a non-planar or a multi-gate device such as a FinFET device or a gate-all-around (GAA) FET device, but the disclosure is not limited thereto. In some embodiments, the HV device may be planar device. In some embodiments, the HV device may be a laterally-diffused metal-oxide semiconductor (LDMOS) device, but the disclosure is not limited thereto. In some embodiments, isolations may be formed in the semiconductor substrate 100 for isolating the first region 102, the second region 104 and the third region 106 from each other, though not shown.

In some embodiments, in operation 22, a plurality of fins 108 are formed in the first region 102. The fins 108 may be patterned by any suitable method. For example, the fins 108 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 104.

In some embodiments, in operation 22, isolation structures 110, e.g., shallow trench isolation (STI) structures, may be interposed in the first region 102. Further, the isolation structures 110 may be interposed between the fins 108, thereby separating the fins 108 from each other, as shown in FIG. 3A. In some embodiments, the second region 104 and the third region 106 are protected during the forming of the fins 108 and the forming of the isolation structures 110.

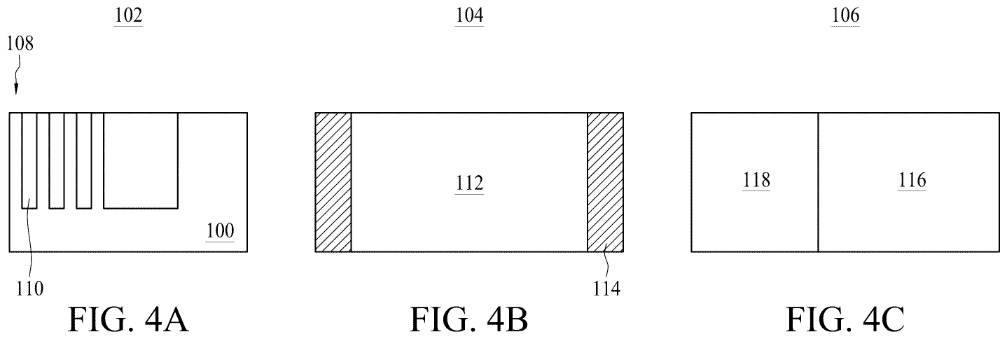

Referring to FIGS. 4A to 4C, in some embodiments, in operation 11, a semiconductor electrode 112 is formed in the semiconductor substrate 100 in the second region 104. In some embodiments, the operation 11 may be performed after the operation 21, but the disclosure is not limited thereto. In some embodiments, well regions 112, 114, 116, and 118 are formed. As shown in FIGS. 4B and 4C, the well region 112 is formed in the second region 104 while the well region 116 is formed in the third region 106. In some embodiments, the well region 112 may be referred to as a semiconductor electrode 112 for a 3D capacitor. In some embodiments, the well region 116 and the semiconductor electrode 112 are simultaneously formed. In such embodiments, the well region 116 and the semiconductor electrode 112 may include dopants of a same conductivity type. For example but not limited thereto, the well region 116 and the semiconductor electrode 112 may include n-type dopants. In some embodiments, a dopant concentration of the well region 116 and a dopant concentration of the semiconductor electrode 112 are the same, but the disclosure is not limited thereto. In some alternative embodiments, the well region 116 and the semiconductor electrode 112 may include different dopant concentrations, but the disclosure is not limited thereto.

Referring to FIG. 4B, in some embodiments, another well region 114 may be formed in the semiconductor substrate 100 in the second region 104. The well region 114 may include dopants of a conductivity type complementary to that of the dopants of the semiconductor electrode 112. For example, when the semiconductor electrode 112 includes n-type dopants, the well region 114 may include p-type dopants. As shown in FIG. 4B, in some embodiments, the well region 114 surrounds the semiconductor electrode 112. In such embodiments, the well region 114 may provide isolation such that the semiconductor electrode 112 is electrically isolated from other elements (not shown).

Referring to FIG. 4C, in some embodiments, the well region 118 is formed in the third region 106 and adjacent to the well region 116. The well region 118 may include dopants having a conductivity type complementary to that of the dopants in the well region 116. For example, when the well region 116 includes n-type dopants, the well region 118 may include p-type dopants. In some embodiments, for a HV device approach, the well region 116 may be referred to as a high voltage n-type well (HVNW) and the well region 118 may be referred to as a high voltage p-type well (HVPW), but the disclosure is not limited thereto.

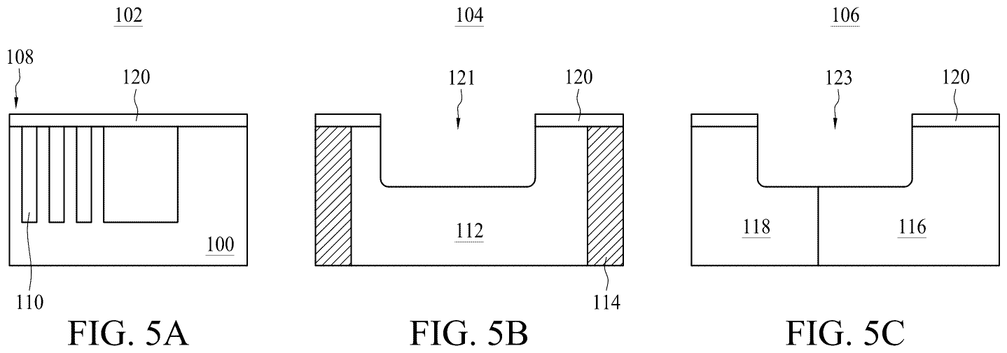

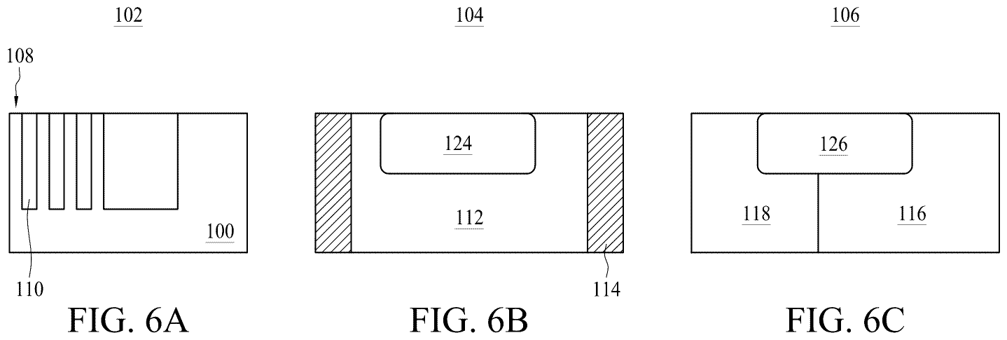

Referring to FIGS. 5A to 5C and 6A to 6C, in some embodiments, operation 12 and operation 23 are performed. In such embodiments, isolation structures are formed in the second region 104 and the third region 106. In some embodiments, the forming of the isolation structures may include further operations. For example, as shown in FIGS. 5A to 5C, a patterned mask layer 120 may be formed over the semiconductor substrate 100. The patterned mask layer 120 may cover the first region 102 but exposes portions of the semiconductor substrate 100 in the second region 104 and the third region 106. In some embodiments, an etching is performed on the semiconductor substrate 100 to remove the portion of the semiconductor substrate 100 exposed through the patterned mask layer 120 from the second region 104 and the third region 106. Accordingly, a recess 121 is formed in the second region 104 and a recess 123 is formed in the third region 106. In some embodiments, a width of the recess 121 and a width of the recess 123 may be similar, but the disclosure is not limited thereto. In some embodiments, a depth of the recess 121 and a depth of the recess 123 may be similar, but the disclosure is not limited thereto.

Referring to FIG. 5B, in some embodiments, the well region 112 is exposed through a bottom and sidewalls of the recess 121. Referring to FIG. 5C, in some embodiments, a portion of the well region 116 and a portion of the well region 118 are exposed through a bottom of the recess 123. Further, a portion of the well region 116 and a portion of the well region 118 are exposed through sidewalls of the recess 123.

Referring to FIGS. 6A to 6C, in some embodiments, the isolation structure 124 is formed in the recess 121 in the second region 104, and the isolation structure 126 is formed in the recess 123 in the third region 106. Further, the recess 121 is filled with the isolation structure 124, and the recess 123 is filled with the isolation structure 126. In some embodiments, the isolation structures 124 and 126 may be field oxide (FOX) structures, but the disclosure is not limited thereto. In some embodiments, top surfaces of the isolation structures 124 and 126 may be aligned (i.e., flush or coplanar) with a top surface of the semiconductor substrate 100. In some alternative embodiments, the top surfaces of the isolation structures 124 and 126 may be higher than the top surface of the semiconductor substrate 100.

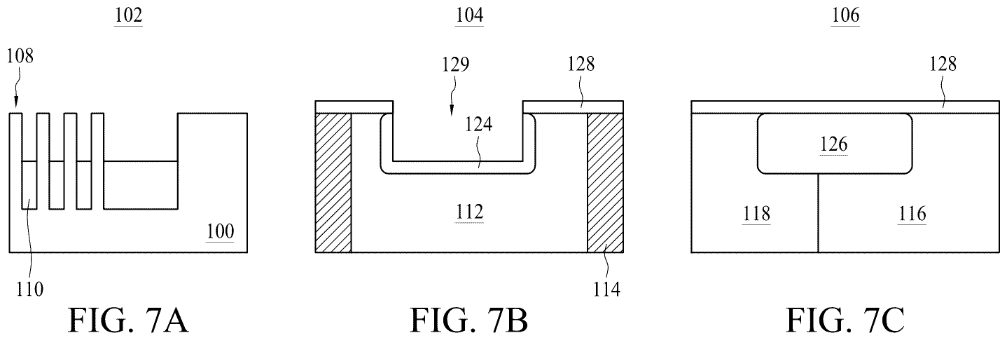

Referring to FIGS. 7A to 7C, in some embodiments, operation 13 and operation 24 are performed. In such embodiments, a portion of the isolation structure 110 is removed from the first region 102, and a portion of the isolation structure 124 is removed from the second region 104. In some embodiments, the operation 13 and the operation 24 may be simultaneously performed. In some embodiments, the operation 13 and the operation 24 may include further operations. For example, a patterned mask layer 128 may be formed over the semiconductor substrate 100. The patterned mask layer 128 may cover the third region 106 but exposes the first region 102 and a portion of the second region 104. In some embodiments, an etching is performed on the semiconductor substrate 100 to remove the portion of the semiconductor substrate 100 exposed through the patterned mask layer 128. Accordingly, portions of the isolation structures 110 in the first region 102 are removed, thereby exposing portions of the fins 108. As shown in FIG. 7A, a top surface and a portion of sidewalls of each fin 108 are exposed after the etching. Further, the top surfaces of the fins 108 are higher than top surfaces of the isolation structures 110 after the etching. In some embodiments, the isolation structures 110 can be described as recessed.

Referring to FIG. 7B, in the second region 104, a portion of the isolation structure 124 is removed to form a dielectric feature 124. Further, a recess 129 is formed in the dielectric feature 124. In some embodiments, a depth of the recess 129 may be between approximately 425 angstroms and approximately 455 angstroms, but the disclosure is not limited thereto. As shown in FIG. 7B, the dielectric feature 124 is exposed through a bottom and sides of the recess 129. In some embodiments, the dielectric feature 124 has a U shape.

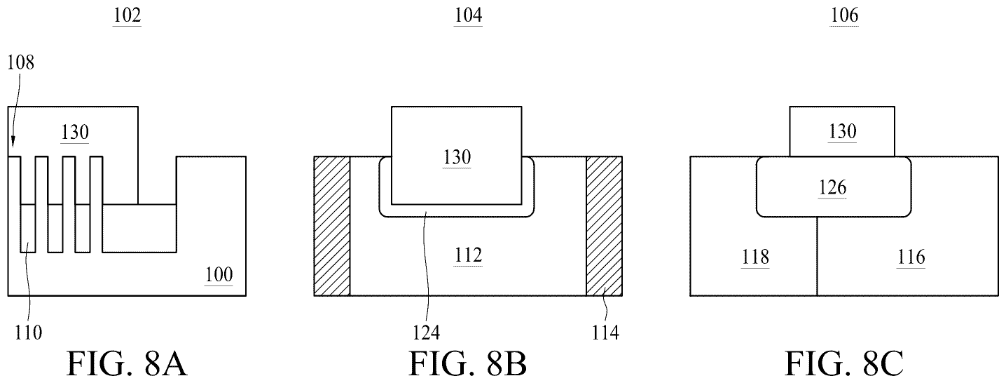

Referring to FIGS. 8A to 8C, in some embodiments, operation 14 and operation 25 are performed. In such embodiments, a sacrificial gate 130 is formed in the first region 102, the second region 104 and the third region 106, respectively. The sacrificial gates 130 in the first region 102, the second region 104 and the third region 106 may be simultaneously formed. In some embodiments, heights of the sacrificial gates 130 in the first region 102, the second region 104 and the third region 106 may be the same, but the disclosure is not limited thereto. In some embodiments, width of the sacrificial gates 130 in the first region 102, the second region 104 and the third region 106 may vary, depending on product designs. In some embodiments, the sacrificial gates 130 respectively include a dielectric layer and a sacrificial semiconductor layer. In some embodiments, the dielectric layer may be a silicon oxide layer, but the disclosure is not limited thereto. In some embodiments, the sacrificial semiconductor layer is made of polysilicon, but the disclosure is not limited thereto. In some embodiments, the sacrificial gates 130 may include sidewall spacers (not shown), respectively. In some embodiments, the sidewall spacers are made of silicon nitride (SiN), silicon carbide (SiC), silicon oxide (SiO), silicon oxynitride (SiON), silicon carbide or any other suitable material, but the disclosure is not limited thereto. In some embodiments, the sidewall spacers are formed by deposition and etch-back operations.

Referring to FIG. 8A, a portion of each fin 108 is covered by the sacrificial gate 130, and such portion may serve as a channel region. Portions of each fin 108 exposed through the sacrificial gate 130 may serve as a source/drain. “Source/drain” may refer to a source or a drain, individually or collectively depending upon the context.

Referring to FIG. 8B, the sacrificial gate 130 is formed over the dielectric feature 124 in the second region 104. Further, a bottom and a portion (i.e., a lower portion) of sidewalls of the sacrificial gate 130 are in contact with the dielectric feature 124. Further, a bottom of the sacrificial gate 130 is lower than a top surface of the semiconductor substrate 100. Additionally, the sacrificial gate 130 is separated from the semiconductor electrode 112 by the dielectric feature 124.

Referring to FIG. 8C, the sacrificial gate 130 in the third region 106 is formed over the isolation structure 126, which may be referred to as a dielectric feature 126. In some embodiments, a bottom of the sacrificial gate 130 is in contact with the dielectric feature 126, while sidewalls of the sacrificial gate 130 are exposed through the semiconductor substrate 100 and the dielectric feature 126. Further, the bottom of the sacrificial gate 130 is flush (i.e., coplanar) with or higher than the top surface of the semiconductor substrate 100.

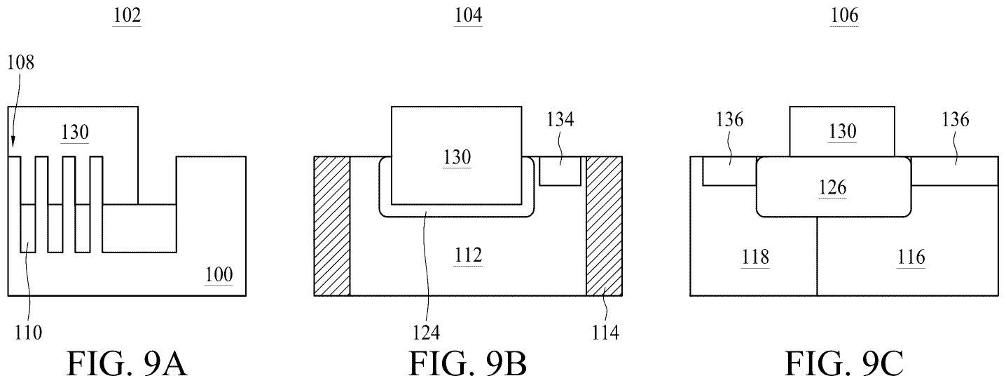

Referring to FIGS. 9A to 9C, in some embodiments, operation 15 is performed to form a doped region 134 in the second region 104. In some embodiments, operation 26 is performed to form a source/drain region 136 in the third region 106. In some embodiments, the operation 15 and the operation 26 may be sequentially performed and integrated into a manufacturing process.

In some embodiments, the operation 26 may further include forming a source/drain region in the first region 102. In such embodiments, the forming of the source/drain region in the first region 102 and the forming of the source/drain region 136 in the third region 106 may be individually performed, depending on process design. In some embodiments, the forming of the source/drain region in the first region 102 may include further operations. For example, portions of the fins 108 that are exposed through the sacrificial gate 130 may be removed, thereby forming recesses in the fins 108. A strained material is then formed in the recesses by an epitaxial (epi) process. In addition, a lattice constant of the strained material may be different from a lattice constant of the fin 108. Accordingly, the source/drain regions (not shown) are formed at two opposite sides of the sacrificial gate 130 in the first region 102 and may serve as stressors that improve carrier mobility.

Referring to FIG. 9C, in some embodiments, the source/drain regions 136 are formed in the third region 106 at two opposite sides of the sacrificial gate 130. In some embodiments, the source/drain region 136 may include dopants having a conductivity type same as that of the well region 116. For example, when the well region 116 includes n-type dopants, the source/drain regions 136 include n-type dopants. In such embodiments, a dopant concentration of the source/drain regions 136 is greater than the dopant concentration of the well region 116. In some embodiments, a bottom of the source/drain region 136 is higher than a bottom of the dielectric feature 126. In some embodiments, a sidewall of the source/drain 136 may be in contact with the dielectric feature 126, but the disclosure is not limited thereto.

Referring to FIG. 9B, in some embodiments, the doped region 134 is formed in the second region 104 and coupled to the semiconductor electrode 112. In some embodiments, the doped region 134 may include dopants having a conductivity type same as that of the semiconductor electrode 112. For example, when the semiconductor electrode 112 includes n-type dopants, the doped region 134 also includes n-type dopants. Further, a dopant concentration of the doped region 134 is greater than the dopant concentration of the semiconductor electrode 112. Additionally, a bottom of the doped region 134 is higher than a bottom of the dielectric feature 124.

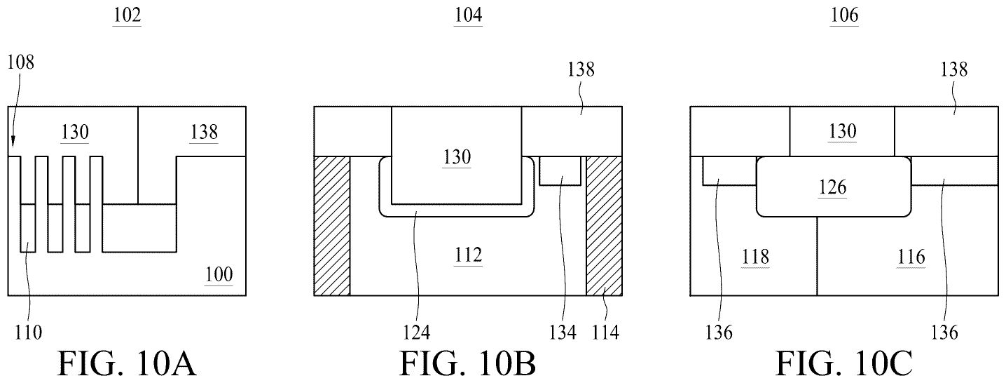

In some embodiments, operation 16 and operation 27 are performed. In some embodiments, the operation 16 and the operation 27 respectively include further operations. For example, referring to FIGS. 10A to 10C, in some embodiments, a dielectric structure 138 is formed over the semiconductor substrate 100. The dielectric structure 138 may include an etch stop layer such as a contact etch stop layer (CESL, not shown) and an inter-layer dielectric (ILD) layer formed over the etch stop layer. In some embodiments, the etch stop layer is conformally formed over the semiconductor substrate 100, and the ILD layer is formed over the etch stop layer and provides a flush or level surface over the semiconductor substrate 100. In some embodiments, a planarization operation may be performed to remove superfluous dielectric material and expose top surfaces of the sacrificial gates 130.

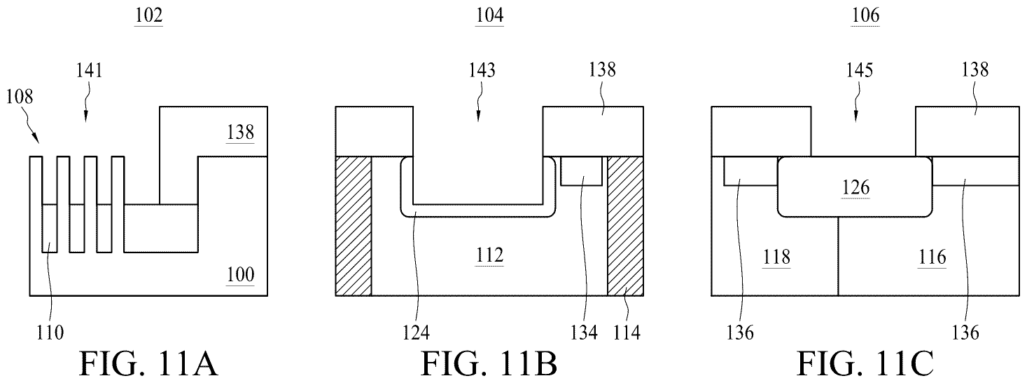

Referring to FIGS. 11A to 11C, the operation 16 and the operation 27 further include removing the sacrificial gates 130 to form gate trenches. As shown in FIG. 11A, the sacrificial gate 130 is removed, thereby forming a gate trench 141 in the first region 102. Further, the fins 108 are exposed through the gate trench 141. As shown in FIG. 11B, the sacrificial gate 130 is removed, thereby forming a gate trench 143 in the second region 104. Further, a portion of the dielectric feature 124 is exposed through a bottom and a lower portion of sidewalls of the gate trench 143, while the dielectric structure 138 is exposed through an upper portion of the sidewalls of the gate trench 143. As shown in FIG. 11C, the sacrificial gate 130 is removed thereby forming a gate trench 145 in the third region 106. Further, the dielectric feature 126 is exposed through a bottom of the gate trench 145 while the dielectric structure 138 is exposed through sidewalls of the gate trench 145.

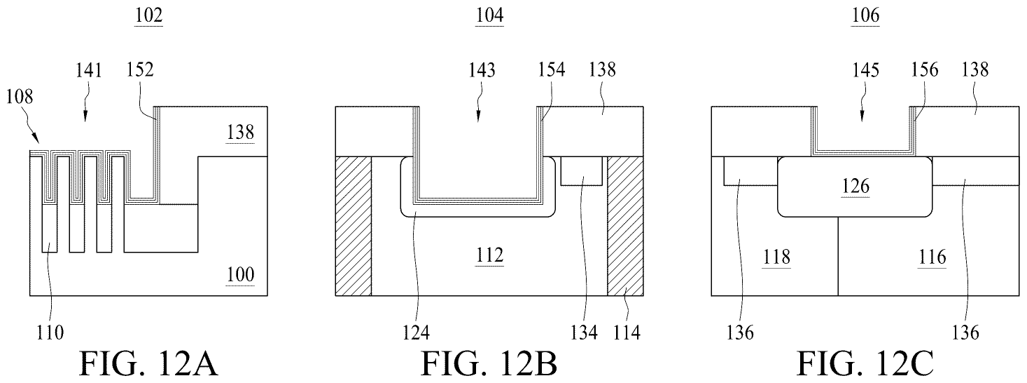

Referring to FIGS. 12A to 12C the operation 16 and the operation 27 further include forming a dielectric layer 152 in the gate trench 141, a dielectric layer 154 in the gate trench 143 and a dielectric layer 156 in the gate trench 145. In some embodiments, the dielectric layers 152, 154 and 156 respectively are multilayered structures, but the disclosure is not limited thereto. As shown in FIGS. 12A to 12C, the dielectric layers 152, 154 and 156 may be conformally formed in the gate trenches 141, 143 and 145.

As shown in FIG. 12A, the dielectric layer 152 covers portions of the fins 108 exposed through the gate trench 141. As shown in FIG. 12B, the dielectric layer 154 covers the portions of the dielectric feature 124 exposed through the bottom and the sidewalls of the gate trench 143, and covers the portions of the dielectric structure 138 exposed through the sidewalls of the gate trench 143. As shown in FIG. 12C, the dielectric layer 156 covers the portions of the dielectric feature 126 exposed through the bottom of the gate trench 145 and the portions of the dielectric structure 138 exposed through the sidewalls of the gate trench 145. The dielectric layers 152, 154 and 156 are simultaneously formed and have same materials. In some embodiments, the dielectric layers 152, 154 and 156 may include a high-k dielectric material having a high dielectric constant, for example, a dielectric constant greater than that of thermal silicon oxide (^{\tilde{ }}3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOₓN_{y}), other suitable metal-oxides, or combinations thereof.

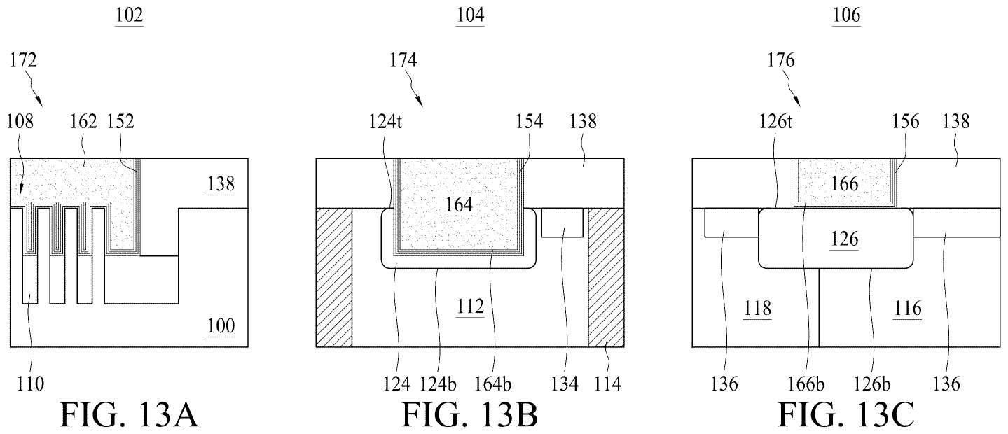

Referring to FIGS. 13A to 13C, the operation 16 further includes filling the gate trench 143 with a metal electrode 164, and the operation 27 further includes forming a metal gate 162 in the gate trench 141 and a metal gate 166 in the gate trench 145. The metal electrode 164 and the metal gates 162 and 166 may be formed by CVD, PVD and/or other suitable processes, followed by a planarization process for removing superfluous materials. Accordingly, the metal gate 162 is formed in the first region 102, the metal electrode 164 is formed in the second region 104, and the metal gate 166 is formed in the third region 106. In some embodiments, the metal electrode 164 and the metal gates 162 and 166 include a same material. For example, when the logic device in the first region 102 and the HV device in the third region 106 are n-type devices, each of the metal electrode 164 and the metal gates 162 and 166 may include an n-type work function metal layer, and the n-type work function metal layer may include titanium (Ti), aluminum (Al), titanium aluminum (TiAl), tantalum carbide (TiC), tantalum carbide nitride (TiCN), tantalum silicon nitride (TaSiN), or a combination thereof. In some alternative embodiments, when the logic device in the first region 102 and the HV device in the third region 106 are p-type devices, each of the metal electrode 164 and the metal gates 162 and 166 may include a p-type work function metal layer, and the p-type work function metal layer may include TiN, TaN, ruthenium (Ru), molybdenum (Mo), tungsten (W), platinum (Pt), TiAl, or a combination thereof.

The metal electrode 164 and the metal gates 162 and 166 may include other layers such as an etch stop layer and/or a diffusion barrier layer, though not shown.

As shown in FIG. 13A, a non-planar device, such as a FinFET device 172, is obtained in the first region 102. The FinFET device 172 includes the metal gate 162, the dielectric layer 152, the channel regions in the fins 108 covered by the metal gate 162, and the source/drain region (not shown).

As shown in FIG. 13C, an HV device 176 is obtained in the third region 106. The HV device 176 includes the metal gate 166, the dielectric layer 156, the dielectric feature 126, and the source/drain region 136. Further, the metal gate 166 and the dielectric layer 156 of the HV device 176 are formed over the dielectric feature 126 and separated from the well regions 116 and 118 by the dielectric feature 126, while the dielectric layer 156 is between the dielectric feature 126 and the metal gate 166. Additionally, the dielectric layer 156 has an U shape.

As shown in FIG. 13B, a 3D capacitor 174 is formed in the second region 104. The 3D capacitor 174 includes the semiconductor electrode 112, the metal electrode 164, the dielectric feature 124 between the metal electrode 164 and the semiconductor electrode 112, and the dielectric layer 154 between the metal electrode 164 and the dielectric feature 124. The dielectric feature 124 and the dielectric layer 154 respectively have a U shape. However, a topmost surface of the dielectric layer 154 is higher than a topmost surface 124t of the dielectric feature 124 in a direction perpendicular to the surface of the semiconductor substrate 100. Further, a dielectric constant of the dielectric layer 154 is greater than a dielectric constant of the dielectric feature 124. In some embodiments, the 3D capacitor 174 further includes the doped region 134 coupled to the semiconductor electrode 112. In some embodiments, the 3D capacitor 174 further includes the well region 114 surrounding the semiconductor electrode 112.

In some embodiments, the 3D capacitor 174 has a first capacitance obtained from a bottom of the metal electrode 164, the dielectric layer 154, the dielectric feature 124, and the semiconductor electrode 112. The 3D capacitor 174 further has a second capacitance obtained from sidewalls of the metal electrode 164, the dielectric layer 154, the dielectric feature 124 and the semiconductor electrode 112 around the sidewalls of the metal electrode 174. In such embodiments, the second capacitance makes the capacitor 174 a “3D”capacitor.

Still referring to FIGS. 13A to 13C, in some embodiments, the dielectric feature 124 and the dielectric feature 126 include same materials such as, for example but not limited thereto, silicon oxide. In some embodiments, the metal electrode 164 and the metal gates 162 and 166 include same materials. For example, the metal electrode 164 and the metal gates 162 and 166 include same n-type work function metal layers. In some embodiments, the dielectric layer 152 between the metal gate 162 and the fins 108, the dielectric layer 154 between the metal electrode 164 and the dielectric feature 124, and the dielectric layer 156 between the metal gate 166 and the dielectric feature 126 include same materials such as, for example but not limited thereto, high-k dielectric layer(s).

In some embodiments, a bottom surface 124b of the dielectric feature 124 of the 3D capacitor 174 and a bottom surface 126b of the dielectric feature 126 of the HV device 176 are aligned (i.e., flush or coplanar) with each other. As mentioned above, the dielectric feature 124 is U-shaped. In some embodiments, the topmost surface 124t of the dielectric feature 124 and a top surface 126t of the dielectric feature 126 are aligned (i.e., flush or coplanar) with each other.

In some embodiments, both the dielectric layer 154 of the 3D capacitor 174 and the dielectric layer 156 of the HV device 176 are U-shaped. A topmost surface of the dielectric layer 154 of the 3D capacitor 174 is aligned (i.e., flush or coplanar) with a topmost surface of the dielectric layer 156 of the HV device 176. In some embodiments, the top surface of the U-shaped dielectric layer 154 and the topmost surface of the U-shaped dielectric layer 156 are aligned (i.e., flush or coplanar) with a top surface of the dielectric structure 138, but the disclosure is not limited thereto. A bottom surface of the dielectric layer 154 of the 3D capacitor 174 is lower than a bottom surface of the dielectric layer 156 of the HV device 176 in the direction perpendicular to the surface of the semiconductor substrate 100. Further, a length of a sidewall portion of the U-shaped dielectric layer 154 of the 3D capacitor 174 is greater than a length of a sidewall portion of the U-shaped dielectric layer 156 of the HV device 176.

In some embodiments, a bottom surface 164b of the metal electrode 164 of the 3D capacitor 176 is between the topmost surface 124t of the dielectric feature 124 and the bottom surface 124b of the dielectric feature 124 in the direction perpendicular to the surface of the semiconductor substrate 100. A bottom surface 166b of the metal gate 166 of the HV device 176 is flush with or higher than the top surface 126t of the dielectric feature 126. In some embodiments, the bottom surface 164b of the metal electrode 164 of the 3D device 174 is lower than the bottom surface 166b of the metal gate 166 of the HV device 176, as shown in FIGS. 13B and 13C. A top surface of the metal electrode 164 of the 3D capacitor 174 and a top surface of the metal gate 166 of the HV device 176 are flush (i.e., flush or coplanar) with each other. In such embodiments, a height of the metal electrode 164 of the 3D capacitor 174 is greater than a height of the metal gate 166 of the HV device 176. A distance between the bottom surface 164b of the metal electrode 164 and the bottom surface 124b of the dielectric feature 124 is less than a distance between the bottom surface 166b of the metal gate 166 and the bottom surface 126b of the dielectric feature 126.

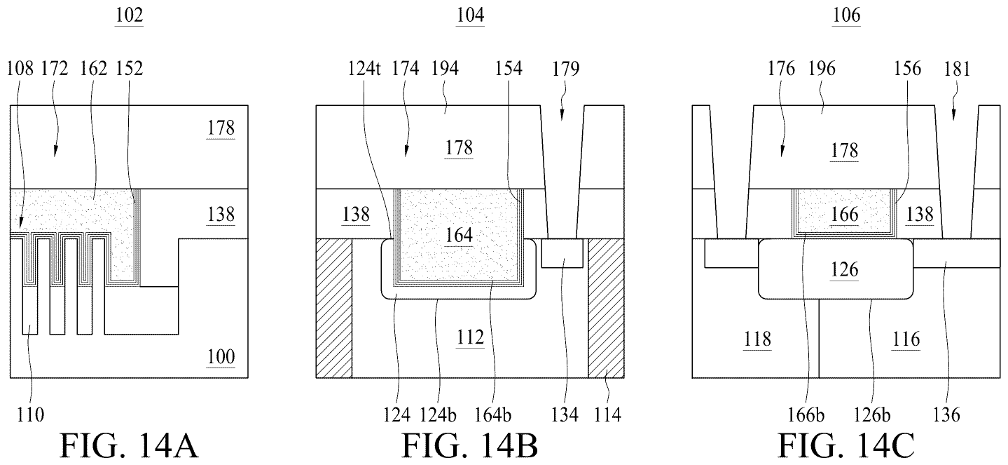

Referring to FIGS. 14A to 14C, in some embodiments, after the forming of the FinFET device 172, the 3D capacitor 174 and the HV device 176, another dielectric structure 178 is formed over the semiconductor substrate 100. In some embodiments, the dielectric structure 178 may include a material same as that of the dielectric structure 138, but the disclosure is not limited thereto. Subsequently, trenches 179 and 181 are formed in the dielectric structure 178. As shown in FIG. 14B, the trench 179 is formed in the dielectric structures 178 and 138 in the second region 104. Further, the trench 179 penetrates the dielectric structures 178 and 138, thus the doped region 134 is exposed through a bottom of the trench 179. As shown in FIG. 14C, the trenches 181 are formed in the dielectric structures 178 and 138 in the third region 106. Further, the trench 181 penetrates the dielectric structures 178 and 138, and thus the source/drain region 136 is exposed through a bottom of the trenches 181. In some embodiments, trenches may be formed in the first region 102 to expose portions of the source/drain of the logic device 172, though not shown.

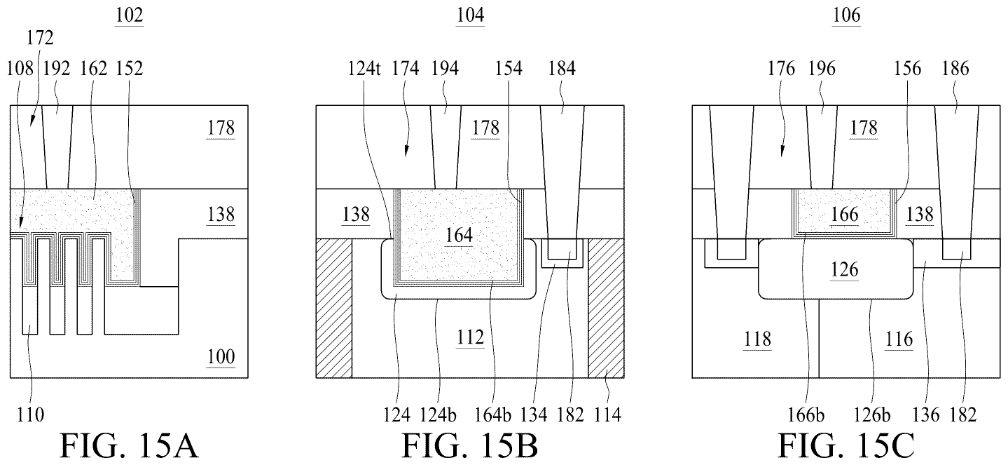

Referring to FIGS. 15A to 15C, a salicide structure 182 is formed in the doped region 134 exposed through the trench 179, and salicide structures 182 are formed in the source/drain regions 136 exposed through the trenches 181. The salicide structure 182 coupled to the doped region 134 is formed as shown in FIG. 15B, and the salicide structures 182 coupled to the source/drain regions 136 are formed as shown in FIG. 15C. In some embodiments, salicide structures 182 may be formed over the source/drain regions of the logic device 172 in the first region 102, though not shown.

Still referring to FIGS. 15A to 15C, in some embodiments, a conductive material is then formed to fill the trenches 179 and 181, followed by a planarization. Accordingly, connecting structures 184 and 186 are formed. As shown in FIGS. 15B and 15C, the connecting structure 184 is coupled to the salicide structure 182 and the doped region 134 in the second region 104, and the connecting structures 186 are coupled to the salicide structures 182 and the source/drain 136 in the third region 106. In some embodiments, more connecting structures may be formed in the first region 102 and coupled to the salicide structures and the source/drain region of the logic device 172. In some embodiments, the connecting structure 184 coupled to the doped region 134 and the connecting structures 186 coupled to the source/drain region 136 may be referred to as a metal-to-drain (MD), but the disclosure is not limited thereto.

Still referring to FIGS. 15A to 15C, in some embodiments, more connecting structures 192, 194, and 196 may be formed. As shown in FIG. 15A, the connecting structure 192 may be formed to couple to the metal gate 162 of the logic device 172 in the first region 102. As shown in FIG. 15B, the connecting structure 194 may be formed to couple to the metal electrode 164 of the 3D capacitor 174 in the second region 104. As shown in FIG. 15C, the connecting structure 196 may be formed to couple to the metal gate 166 of the HV device 176 in the third region 106. In some embodiments, each of the connecting structures 192, 194 and 196 may be referred to as a metal-to-gate (MG) or a metal-to-poly (MP), but the disclosure is not limited thereto. In some embodiments, MP (or MG) may be formed prior to, after, or simultaneously with the forming of the MD.

According to the method 10 and the method 20, the formation of the logic device 172, the 3D capacitor 174, and the HV device 176 is integrated into one manufacturing process. Further, the operation for forming the semiconductor electrode 112 (shown in FIG. 4B) can be performed simultaneously with the forming of the well region 116 (shown in FIG. 4C), the operation for forming the recess 121 (shown in FIG. 5B) can be performed simultaneously with the forming of the recess 123 (shown in FIG. 5C), the operation for forming the dielectric feature 124 (shown in FIG. 7B) can be performed simultaneously with the recessing of the isolation structures 110 (shown in FIG. 7A), and the forming of the metal electrode 164 can be performed simultaneously with the forming of the metal gate 162 and 166. Accordingly, no extra photomask or extra photolithography operation is needed in the method 10 and the method 20.

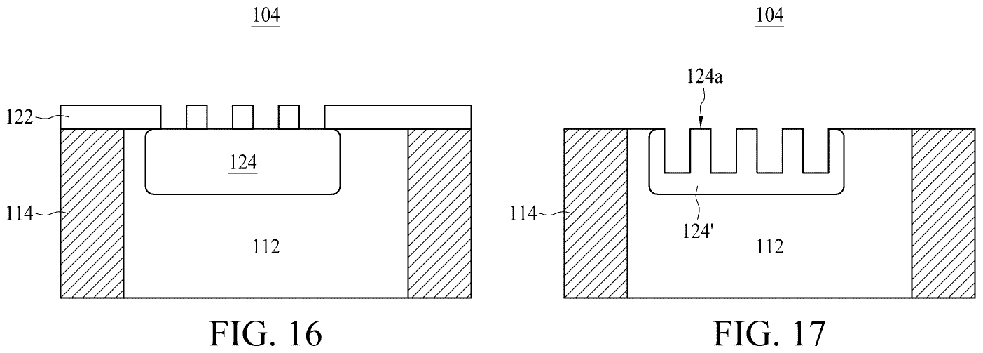

Referring to FIGS. 16 to 20, in some embodiments, the forming of the dielectric feature 124 may include further operations. For example, a semiconductor substrate 100 may be received, and a semiconductor electrode 112 may be formed in the semiconductor substrate 100, as described with reference to operation 11. An isolation structure 124 may be formed in operation 12. A portion of the isolation structure 124 may be removed in operation 13. In such embodiments, a patterned mask layer 122 may be formed over the semiconductor substrate 100, as shown in FIG. 16. In some embodiments, the patterned mask layer 122 may be formed over the third region 106, though not shown in FIG. 16.

Referring to FIG. 17, in operation 13, portions of the isolation structure 124 that are exposed through the patterned mask layer 122 are removed to form a dielectric feature 124′. As shown in FIG. 17, the dielectric feature 124′may include a plurality of teeth 124a.

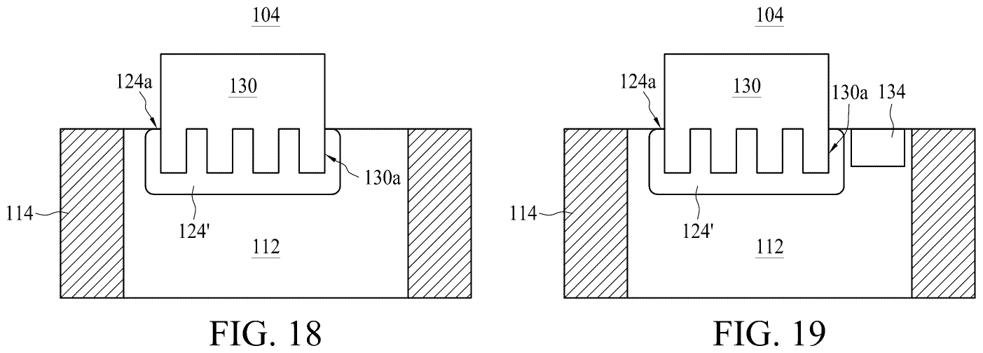

Referring to FIG. 18, in some embodiments, in operation 14, a sacrificial gate 130 is formed over the dielectric feature 124′. As mentioned above, other sacrificial gates 130 may be formed in the first region 102 and/or the third region 106, though not shown. As shown in FIG. 18, the sacrificial gate 130 formed in the second region 104 may include a plurality of teeth 130a interleaved with the teeth 124a of the dielectric feature 124′.

Referring to FIG. 19, in some embodiments, in operation 15, a doped region 134 is formed in the semiconductor substrate 100 in the second region 104. Further, the doped region 134 is coupled to the semiconductor electrode 112.

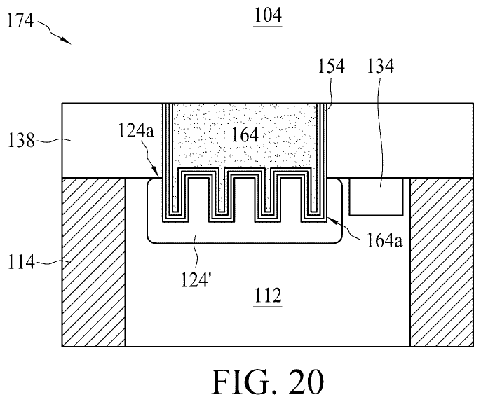

Referring to FIG. 20, in some embodiments, in operation 16, the sacrificial gate 130 is replaced with a dielectric layer 154 and a metal electrode 164. As shown in FIG. 20, in some embodiments, a dielectric structure 138 is formed over the semiconductor substrate 100. Subsequently, the sacrificial gate 130 is removed to form a gate trench (not shown). The dielectric layer 154 and the metal electrode 164 are then formed in the gate trench. The forming of the dielectric structure 138, the removing of the sacrificial gate 130, the forming of the dielectric layer 154 and the forming of the metal electrode 164 may be similar to those described above; therefore, repeated descriptions are omitted. Accordingly, a 3D capacitor 174 is obtained. As shown in FIG. 20, the metal electrode 164 may include a plurality of teeth 164a interleaved with the teeth 124a of the dielectric feature 124′. In some embodiments, a surface area of the metal electrode 164 is increased due to the teeth 124a of the dielectric feature 124′. Accordingly, a capacitance of the 3D capacitor 174 is further increased.

The present disclosure provides a semiconductor structure including a 3D capacitor, a FinFET device and a HV device, and a method of manufacturing the same. In some embodiments, the method for forming the 3D capacitor can be integrated with the method for forming the FinFET device and the method for forming the HV device. Further, a capacitance of the 3D capacitor is increased due to increased surface area in sidewalls of a metal electrode. In some embodiments, by forming a dielectric feature having teeth, a surface area of the 3D capacitor is further increased, thereby increasing the capacitance.

In an aspect of the present disclosure, a semiconductor structure including a 3D capacitor is provided. The semiconductor structure includes a semiconductor substrate having a first region and a second region, a 3D capacitor in the first region, and an HV device in the second region. The 3D capacitor includes a semiconductor electrode, a metal electrode over the semiconductor electrode, a first dielectric feature between the metal electrode and the semiconductor electrode, and a first dielectric layer between the first dielectric feature and the metal electrode. The HV device includes a metal gate, a second dielectric feature between the metal gate and the semiconductor substrate, and a second dielectric layer between the second dielectric feature and the metal gate. The first dielectric feature and the second dielectric feature include same materials. The metal electrode and the metal gate include same materials. The first dielectric layer and the second dielectric layer include same materials.

In another aspect of the present disclosure, a semiconductor 3D capacitor is provided. The semiconductor 3D capacitor includes a semiconductor electrode disposed in a semiconductor substrate, a metal electrode over the semiconductor electrode, and an isolation structure between the semiconductor electrode and the metal electrode. The isolation structure includes a dielectric feature between the semiconductor electrode and the metal electrode, and a dielectric layer between the dielectric feature and the metal electrode. A bottom surface of the metal electrode is between a topmost surface of the dielectric feature and a bottom surface of the dielectric feature in a direction perpendicular to a surface of the semiconductor substrate.

In yet another aspect of the present disclosure, a method for forming a semiconductor structure is provided. The method includes following operations. A semiconductor electrode is formed in a semiconductor substrate. An isolation structure is formed in the semiconductor substrate. A portion of the isolation structure is removed to form a dielectric feature. A sacrificial gate is formed over the dielectric feature. The sacrificial gate is replaced with a dielectric layer and a metal electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure comprising:
a semiconductor substrate having a first region and a second region;
a 3D capacitor in the first region, wherein the 3D capacitor comprises:
a semiconductor electrode;
a metal electrode over the semiconductor electrode;
a first dielectric feature between the metal electrode and the semiconductor electrode; and
a first dielectric layer between the first dielectric feature and the metal electrode; and
a high voltage (HV) device in the second region, wherein the HV device comprises:
a metal gate;
a second dielectric feature between the metal gate and the semiconductor substrate; and
a second dielectric layer between the second dielectric feature and the metal gate, wherein the first dielectric feature and the second dielectric feature comprise same materials, the metal electrode and the metal gate comprise same materials, and the first dielectric layer and the second dielectric layer comprise same materials.

2. The semiconductor structure of claim 1, wherein the 3D capacitor further comprises a doped region disposed in the semiconductor substrate in the first region, wherein the doped region is coupled to the semiconductor electrode.

3. The semiconductor structure of claim 1, wherein a bottom surface of the first dielectric feature of the 3D capacitor and a bottom surface of the second dielectric feature of the HV device are flush.

4. The semiconductor structure of claim 1, wherein a height of the metal electrode of the 3D capacitor is greater than a height of the metal gate of the HV device.

5. The semiconductor structure of claim 1, wherein a top surface of the metal electrode of the 3D capacitor and a top surface of the metal gate of the HV device are flush.

6. The semiconductor structure of claim 1, wherein a distance between a bottom surface of the metal electrode of the 3D capacitor and a bottom surface of the first dielectric feature of the 3D capacitor is less than a distance between a bottom surface of the metal gate of the HV device and a bottom surface of the second dielectric feature of the HV device.

7. The semiconductor structure of claim 1, wherein the first dielectric layer of the 3D capacitor has a first sidewall portion, the second dielectric layer of the HV device has a second sidewall portion, and a length of the first sidewall portion is greater than a length of the second sidewall portion.

8. The semiconductor structure of claim 1, further comprising a well region disposed in the semiconductor substrate in the second region, wherein the HV device is disposed over the well region, and the well region and the semiconductor electrode of the 3D capacitor comprise same dopants.

9. A semiconductor 3D capacitor comprising:
a semiconductor electrode disposed in a semiconductor substrate;
a metal electrode over the semiconductor electrode; and
an isolation structure between the semiconductor electrode and the metal electrode, wherein the isolation structure comprises:
a dielectric feature between the semiconductor electrode and the metal electrode; and
a dielectric layer between the dielectric feature and the metal electrode, wherein a bottom surface of the metal electrode is between a topmost surface of the dielectric feature and a bottom surface of the dielectric feature in a direction perpendicular to a surface of the semiconductor substrate.

10. The semiconductor 3D capacitor of claim 9, wherein the dielectric feature and the dielectric layer respectively comprise a U shape.

11. The semiconductor 3D capacitor of claim 9, wherein a dielectric constant of the dielectric layer is greater than a dielectric constant of the dielectric feature.

12. The semiconductor 3D capacitor of claim 9, wherein a topmost surface of the dielectric layer is higher than the topmost surface of the dielectric feature in the direction perpendicular to the surface of the semiconductor substrate.

13. The semiconductor 3D capacitor of claim 9, further comprising a well region surrounding the semiconductor electrode.

14. The semiconductor 3D capacitor of claim 13, wherein the semiconductor electrode comprises a first conductivity type, and the well region comprises a second conductivity type complementary to the first conductivity type.

15. The semiconductor 3D capacitor of claim 9, further comprising a doped region coupled to the semiconductor electrode, where in the doped region and the semiconductor electrode comprise a same conductivity type.

16. The semiconductor 3D capacitor of claim 15, wherein a dopant concentration of the doped region is greater than a dopant concentration of the semiconductor electrode.

17. A method for forming a semiconductor structure, comprising:
forming a semiconductor electrode in a semiconductor substrate;
forming an isolation structure in the semiconductor substrate;
removing a portion of the isolation structure to form a dielectric feature;
forming a sacrificial gate over the dielectric feature; and
replacing the sacrificial gate with a dielectric layer and a metal electrode.

18. The method of claim 17, further comprising forming a doped region in the semiconductor substrate, wherein the doped region is coupled to the semiconductor electrode.

19. The method of claim 18, further comprising forming a salicide structure coupled to the doped region.

20. The method of claim 17, wherein the replacing of the sacrificial gate with the dielectric layer and the metal electrode further comprises:
forming a dielectric structure over the semiconductor substrate;
removing the sacrificial gate to form a gate trench in the dielectric structure;
forming the dielectric layer in the gate trench; and
filling the gate trench with the metal electrode.
